(19) United States
(12) Patent Application Publication
(10) Pub. No.: US 2011/0084586 A1
(43) Pub. Date: Apr. 14, 2011

(54) LED recessed light with heat sink

(76) Inventors: You Chuen Lain, Sinjhuang City (TW); Yen Wei Pen, Sinjhuang City (TW); Meng Hsieh Chou, Sinjhuang City (TW)

(21) Appl. No.: 12/703,765

(22) Filed: Feb. 11, 2010

(30) Foreign Application Priority Data
Oct. 9, 2009 (TW) 098218582

(51) Int. Cl. H01L 33/64

(52) U.S. Cl. 313/46; 257/E33.075

(57) ABSTRACT

An LED recessed light with heat sink comprises heat sink base, an LED illumination module, a sleeve and a transparent board. The heat sink base has an upper surface, a bottom surface and a side wall connected the surface to the bottom. The LED illumination module is mounted on the bottom surface of heat sink base. The sleeve has first open end, which is formed with a fixed portion, and a second open end, the fixed portion of the sleeve is mounted at the side wall of the heat sink base, so as to the first open end of the sleeve is located on the bottom surface of the heat sink base. And the transparent board is located on the second open end of the sleeve to cover the second open end.

### FIELD OF THE INVENTION

The present invention relates to an LED recessed light with heat sink, and in particular to an LED recessed light capable of increasing heat dissipation.

### DESCRIPTION OF THE RELATED ART

Since light emitting diodes (LEDs) feature the high brightness, power saving and long life expectancy advantages, they have been used extensively for the illumination of lamps. Several LED lamps are usually connected to form an LED lamp set, and the position of each lamp can be adjusted to achieve an illumination effect to meet the requirements for a large projecting area and a high brightness. These LED lamp sets are used as illuminating devices indoors and outdoors. However, it is necessary to plan the LED lamps and the layout of different projecting areas, so as to differentiate the projecting area for each LED lamp with a different distance from the LED lamp and the projecting area, and prevent an uneven brightness of the light projected from the LED lamps onto the projecting areas. Therefore, it is an important subject for manufacturers in the related field to design an LED lamp with good directionality and even brightness.

As is generally known in the art, use has been made of varying kinds of illumination lamps for lightening or illuminating objects at night or indoors. Such illumination lamps are supplied with electric energy from a power source and convert the electric energy to light energy, thereby producing a beam of light for illumination. Typical examples of the illumination lamps include a glow lamp and a fluorescent lamp.

Widely used in recent years is a Light Emitting Diode (LED) illumination lamp that has a benefit of providing illumination of different colors, although higher in price than the typical lamps referred to above. However, the LED illumination lamp poses a drawback in that it tends to be heated up and shows decreased efficiency when used for more than a predetermined time period. Use of the LED lamp for a prolonged period of time may result in excessive heat generation, thus shortening the life span of the lamp.

### SUMMARY OF THE INVENTION

An object of the present invention is to provide an LED recessed light with heat sink capable of increasing heat dissipation.

To achieve the above-mentioned object, the present invention includes an LED recessed light with heat sink comprises heat sink base, an LED illumination module, a sleeve and a transparent board. The heat sink base has an upper surface, a bottom surface and a side wall connected the surface to the bottom. The LED illumination module is mounted on the bottom surface of heat sink base. The sleeve has first open end, which is formed with a fixed portion, and a second open end, the fixed portion of the sleeve is mounted at the side wall of the heat sink base, so as to the first open end of the sleeve is located on the bottom surface of the heat sink base. And the transparent board is located on the second open end of the sleeve to cover the second open end.

### BRIEF DESCRIPTION OF THE DRAWINGS

FIG. 1 is an exploded view of an LED recessed light with heat sink of the present invention

FIG. 2 is a cross-sectional view of assembly drawing of the FIG. 1.

### DETAILED DESCRIPTION OF THE INVENTION

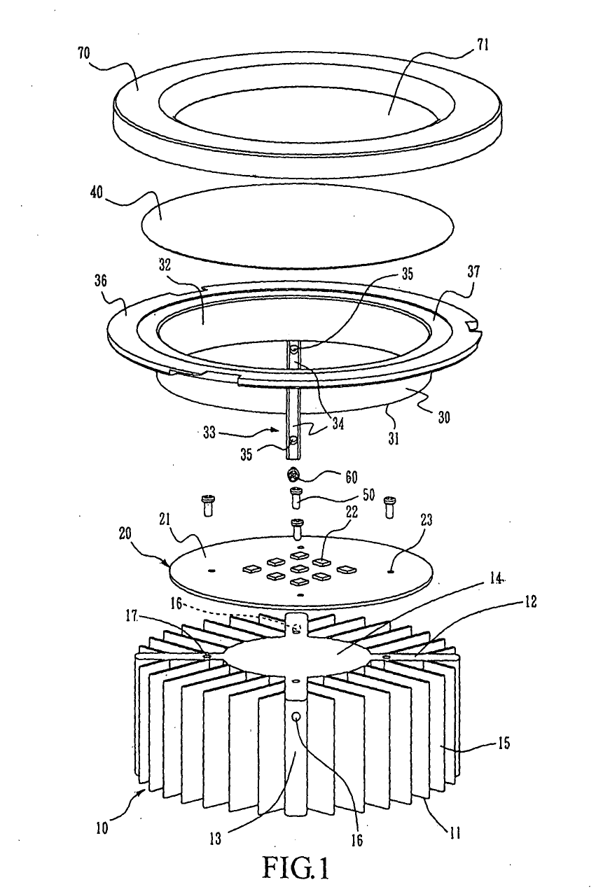

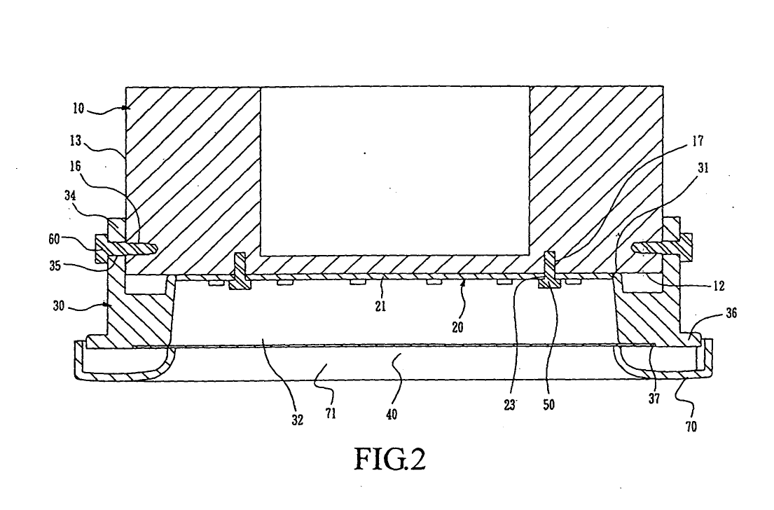

Referring to FIG. 1-FIG. 2, an LED recessed light with heat sink of the present invention includes a heat sink base 10, an LED illumination module 20, a sleeve 30, a transparent board 40 and a decorating board 50. Wherein

The heat sink base 10 has an upper surface 11, a bottom surface 12, which is formed with first fixed holes 17, and a side wall 13, which is formed with second fixed holes 16, the side wall 13 is penetrated from the upper surface 11 and the bottom surface 12. The central of the heat sink base 10 has a cylinder base 14, which is formed with heat sinks 15.

The LED illumination module 20, which includes a print circuit board 21 and a plurality of LED 22 are located on the print circuit board 22, wherein the print circuit board 22 has third fixed holes 23 correspond to the first fixed holes 17, so that the print circuit board 21 may mounted on the bottom surface 12 of the heat sink base 10 by screwed element 50.

The sleeve 30 has a first open end 31, which is formed with a fixed portion 33, and a second open end 32, the fixed portion 33 of the sleeve 30 is mounted at the side wall 13 of the heat sink base 10, so as to the first open end 31 of the sleeve 30 is located on the bottom surface 12 of the heat sink base 10, then LED illumination module 20 is located within the sleeve 30. In the embodiment, the fixed portion 33 of the sleeve 30 is two fixed posts 34 extended from the first open end 31 of the sleeve 30. Wherein fixed post 34 are formed with forth fixed holes 35 correspond to the second fixed holes 16 of the heat sink base 10, so as to the sleeve 30 may fixed at the side wall 13 of the heat sink base 10 by a fixed element 60, then the first open end 31 of the sleeve 30 is located on the bottom surface 12 of the heat sink base 10. Further the second open end 32 of the sleeve 30 is formed with an external flange 35 having a cavity 37.

The transparent board 40 is located within the cavity 37 of the sleeve 30 to cover the second open end 32.

The decorating board 50 is fixed at the second open end 32 of the sleeve 30 and formed with a penetrated hole 71 correspond to the LED illumination module 20,

While the present has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modification.

What is claimed is:

1. An LED recessed light with heat sink comprising:
A heat sink base having an upper surface, a bottom surface and a side wall connected the surface to the bottom;
An LED illumination module mounted on the bottom surface of heat sink base;
A sleeve having a first open end, which is formed with a fixed portion, and a second open end, the fixed portion of the sleeve mounted at the side wall of the heat sink base, so as to the first open end of the sleeve is located on the bottom surface of the heat sink base, then LED illumination module is located within the sleeve; and
A transparent board located on the second open end of the sleeve to cover the second open end.

2. The LED recessed light with heat sink according to claim 1, wherein the heat sink base has a circular cylinder and a plurality of heat sinks are formed at the periphery of the circular cylinder.

3. The LED recessed light with heat sink according to claim 1, wherein the fixed portion of the sleeve is fixed at the side wall of the heat sink base by at least a fixed element.

4. The LED recessed light with heat sink according to claim 3, wherein the fixed portion of the sleeve is two fixed posts extended from the first open end of the sleeve.

5. The LED recessed light with heat sink according to claim 4, wherein the fixed post is formed with forth fixed hole, the side wall of heat sink base is formed with second fixed holes correspond to the forth fixed holes of the fixed posts, so as to the fixed element may penetrated from the second fixed holes of the heat sink base and the forth fixed hole of the sleeve, then the sleeve is fixed at the heat sink base.

6. The LED recessed light with heat sink according to claim 1, wherein the LED illumination module includes a print circuit board, which is mounted on the heat sink base, and LED arranged on the print circuit board.

7. The LED recessed light with heat sink according to claim 6, wherein the bottom surface of the heat sink base is formed with first fixed holes, and the print circuit board is formed with third fixed holes, so that the print circuit board is mounted at the heat sink base by a screwed element.

8. The LED recessed light with heat sink according to claim 1, wherein the second open end of the sleeve is formed with an external flange, which has a cavity.

9. The LED recessed light with heat sink according to claim 6, wherein further comprising a decorating board, which is fixed at the second open end of the sleeve and is formed with a penetrated hole correspond to the LED illumination module.
